(19) United States
(12) Patent Application Publication
(10) Pub. No.: US 2016/0033557 A1
(43) Pub. Date: Feb. 4, 2016

(54) ASSEMBLY OF CURRENT SENSOR AND POWER CONDUCTOR

(71) Applicant: HYUNDAI MOBIS CO., LTD., Seoul (KR)

(72) Inventor: Cheon HWANGBO, Yongin-si (KR)

(73) Assignee: HYUNDAI MOBIS CO., LTD., Seoul (KR)

(21) Appl. No.: 14/813,281

(22) Filed: Jul. 30, 2015

(30) Foreign Application Priority Data
Aug. 4, 2014 (KR) 10-2014-0099807

(51) Int. Cl. G01R 19/00; H01B 5/02; H01B 7/00; G01R 1/04

(52) U.S. Cl. CPC G01R 19/0092; G01R 1/0408; H01B 5/02; H01B 7/0081

(57) ABSTRACT

An assembly of a current sensor and a power conductor may include a first conductor, a second conductor spaced apart from the first conductor, a third conductor connecting one end of the first conductor to one end of the second conductor, and a fourth conductor vertically spaced apart from the third conductor and connecting one end of the first conductor to one end of the second conductor, a fixed space being defined between the third and fourth conductors.

### CROSS-REFERENCE(S) TO RELATED APPLICATIONS

This application claims the benefit under 35 USC 119(a) of Korean Patent Application No. 10-2014-0099807 filed on Aug. 4, 2014 in the Korean Intellectual Property Office, the entire disclosure of which is incorporated herein by reference in its entirety.

### BACKGROUND

1. Field

Embodiments of the present application relate to an assembly of a current sensor and a power conductor capable of reducing crosstalk in peripheral electric devices and of realizing miniaturization/lightening by vertically arranging conductors included in a power conductor at regular intervals to sense magnetic fields and to measure currents using a current sensor.

2. Description of Related Art

FIG. 1 is a perspective view illustrating a structure of a conventional turn-shaped conductor according to the related art. Referring to FIG. 1, an existing power system for an eco-friendly vehicle (including a battery, an inverter, a converter, and a motor) is designed such that each conductor for power transfer (busbar or cable) 10 has a structure in which an electric source or a load is connected to a power switch module, a power conversion board, and a battery so as to be assembled together with a current sensor.

An existing specific current sensor makes optimal current sensor output when magnetic fields 3 in opposite directions are symmetrically formed around the current sensor on the basis of the current sensor. In order for the current sensor to make the optimal sensor output, the turn-shaped conductor having a structure in which the conductors (busbars) 10 pass by both sides of the current sensor and are returned is used, and the conductors (busbars) 10 at both sides of the current sensor are symmetrically designed on the basis of an inflection portion.

In more detail, currents S longitudinally flow along the left and right of the current sensor. In this case, the magnetic fields 2 and 3 generated at both sides of the current sensor by the currents S flowing through the conductors are directed toward a center of the current sensor or directed out of the center. That is, the currents (S) symmetrically flow beside both sides of the current sensor, thereby symmetrically forming the magnetic fields 3. In this case, the current sensor recognizes different magnetic field directions to exhibit optimal performance.

FIGS. 2A-2C are perspective views illustrating a structural problem when the conventional turn-shaped conductor is used according to the related art. Referring to FIGS. 2A-2C, when a power conversion device module is miniaturized and lightened in order to improve fuel efficiency and duration time of a battery and secure spaces of a compartment and a trunk, each conductor 10 in a current sensor module has to be miniaturized and lightened. However, when the curved conductor 10 is used, the whole size of an assembly of a current sensor and a conductor is increased. Therefore, there is a problem in that it is difficult to design the compact current sensor module.

Referring to FIG. 2A, since electromagnetic interference (inductive coupling) is generated between a magnetic field generated by a current flowing through an inflection portion 15 between conductors and a magnetic field generated by a current flowing through another conductor (low-voltage signal line), crosstalk may occur in a surrounding another low-voltage board circuit. In this case, one of causes by which the electromagnetic interference (inductive coupling) is generated is because interfering conductors are arranged to be close to and in parallel with each other. If two conductors (a conductor and a low-voltage signal line) are perpendicular to each other, the conductors have a small influence on each other. On the other hand, if the conductors are not perpendicular to each other or are located close to each other, a variation in voltage may be generated by induced electromotive force.

Referring to FIG. 2B, since a path returned in a curved form is connected again to a path far therefrom in a unidirectional conductor for inverter-motor output 10 when the unidirectional conductor 10 is designed, two or more inflection portions 15 are generated in the unidirectional conductor 10. For this reason, since the conductor 10 has an increased volume and weight and has an asymmetrical shape so that currents and magnetic fields are asymmetrically formed, the current sensor has reduced performance. In a busbar structure in which the inflection portions 15 are generated at two or more positions, a method is provided in which the conductor 10 is designed to have an asymmetrical cross-sectional area such that current densities and magnetic densities are symmetrically formed.

However, there is a problem in that the whole size of the assembly is increased when the cross-sectional area of the conductor 10 is increased and decreasing the cross-sectional area of the conductor 10 has a limit in terms of a rated current and an increase in temperature. In addition, there is a problem in that, when the conductor 10 is arranged far away to have an asymmetrical shape, the power conductor has an increased size as a whole and it is difficult to design the conductor having an asymmetrical shape.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one a general aspect, an assembly of a current sensor and a power conductor may include a first conductor, a second conductor spaced apart from the first conductor, a third conductor connecting one end of the first conductor to one end of the second conductor, and a fourth conductor vertically spaced apart from the third conductor and connecting one end of the first conductor to one end of the second conductor, a fixed space being defined between the third and fourth conductors.

The assembly may include a current sensor installed in the fixed space to sense a magnetic field formed by the third conductor and a magnetic field formed by the fourth conductor so as to measure currents flowing therethrough.

The assembly may be configured such that the first circuit module comprises an insulator.

The assembly may include an insulator arranged between the current sensor and the third conductor.

The assembly may include a second circuit module installed between the current sensor and the fourth conductor to be connected to the current sensor.

The assembly may be configured such that the second circuit module comprises an insulator.

The assembly may include an insulator arranged between the current sensor and the fourth conductor.

The assembly may be configured such that at least one of the first, the second, the third, and the fourth conductors comprises an insulator or a shield substance.

The assembly may be configured such that the third and the fourth conductors are arranged alternately with each other.

The assembly may be configured such that the third or the fourth conductor has any one of a regular hexahedron shape, a shape bent at a right angle, a polyhedral shape, a cylindrical shape, and a streamlined shape.

The assembly may be configured such that a position and an area of the third and of the fourth conductors are symmetrical or are asymmetrical to each other.

The assembly may be configured such that a current flowing in each path of the third and of the fourth conductors is a half of a current supplied to the assembly.

The assembly may be configured such that the insulator or the shield substance is formed in an injection molding process.

Other features and aspects will be apparent from the following detailed description, the drawings, and the claims.

### BRIEF DESCRIPTION OF THE DRAWINGS

FIG. 1 is a perspective view illustrating a structure of a conventional turn-shaped conductor according to the related art.

FIGS. 2A-2C are perspective views illustrating a structural problem when the conventional turn-shaped conductor is used according to the related art.

FIG. 3 is a perspective view illustrating an example of a structure of an assembly of a current sensor and a power conductor.

FIG. 4 is a front view illustrating an example of the structure of the assembly of a current sensor and a power conductor.

FIG. 5 is a side view illustrating an example of the structure of the assembly of a current sensor and a power conductor

FIG. 6 is a detailed view illustrating an example of a current sensor in the assembly of a current sensor and a power conductor

FIGS. 7A-7F are conceptual views illustrating various structural examples of the assembly of a current sensor and a power conductor.

FIG. 8 is a conceptual view illustrating an example of a shape of one unit conductor (busbar) in the assembly of a current sensor and a power conductor.

FIG. 9 is a conceptual view illustrating an example of a cut surface of the unit conductor (busbar) in the assembly of a current sensor and a power conductor.

FIG. 10 is a conceptual view illustrating an example of a connection angle between unit conductors (busbars) in the assembly of a current sensor and a power conductor.

FIG. 11 is a conceptual view illustrating an example of a system to which the assembly of a current sensor and a power conductor.

FIG. 12 is a comparison view comparing the structure of the assembly of a current sensor and a power conductor according to a conventional technique with an embodiment of the present application.

FIGS. 13A-13B are comparison views comparing the structure of the assembly of a current sensor and a power conductor according to a conventional technique with an embodiment of the present application.

FIGS. 14A-14B are comparison views comparing the structure of the assembly of a current sensor and a power conductor according to a conventional technique with an embodiment of the present application.

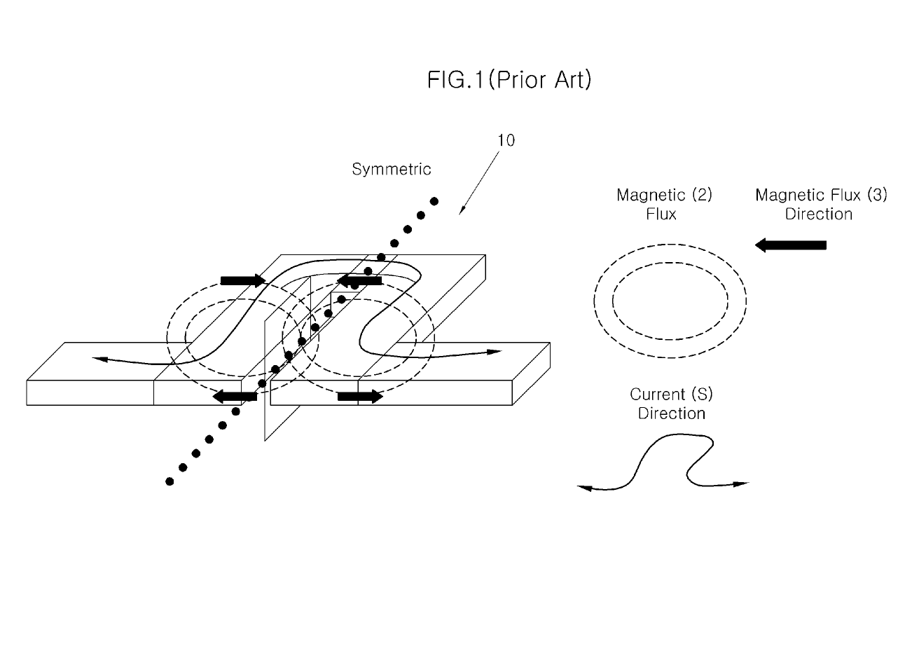

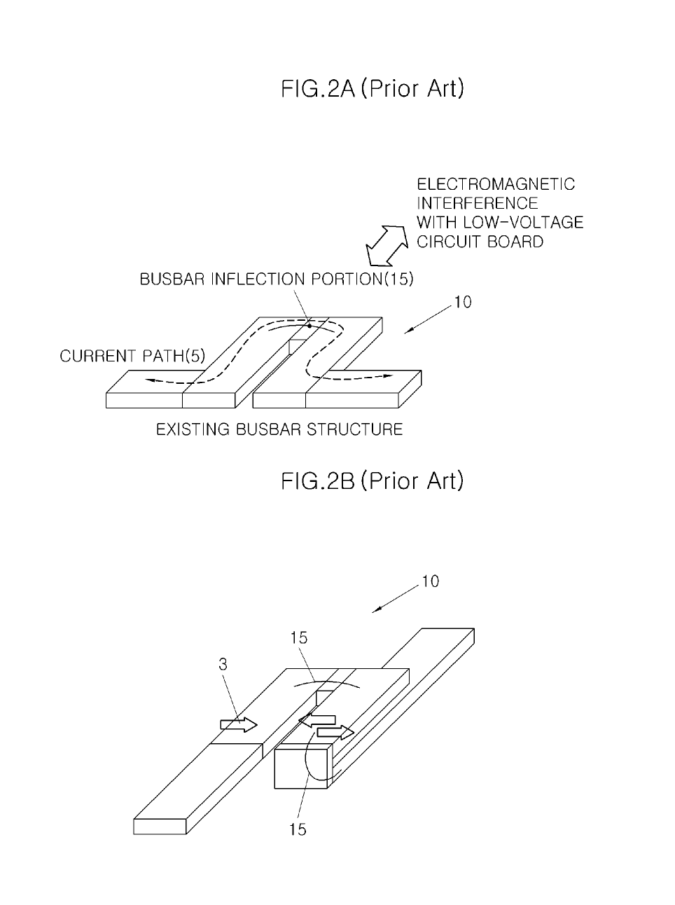

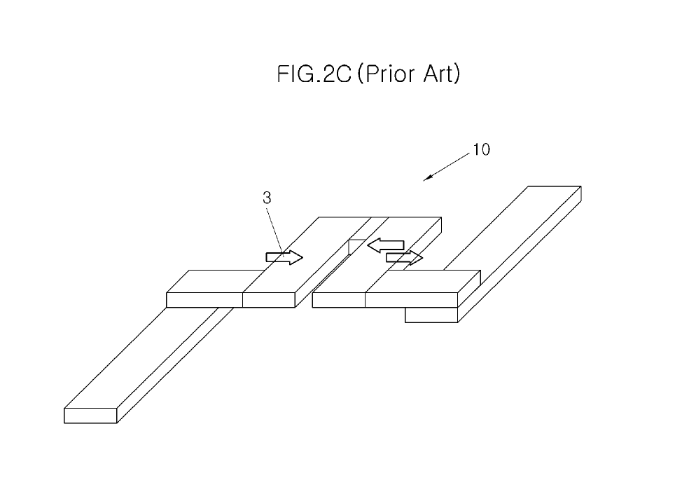

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations described is an example; however, the sequence of and/or operations is not limited to that set forth herein and may be changed as is known in the art, with the exception of steps and/or operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

It is noted that the terminology used in the specification of the present application is for the purpose of describing particular embodiments only and is not intended to limit the application. Unless otherwise defined, all terms, including technical and scientific terms, used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. In addition, it should be understood that the accompanying drawings are merely examples given for the purpose of providing a description of embodiments according to the concept of the present application. Accordingly, various variations may be performed on embodiments of the present application, and it should be understood that the scope and spirit of the present application will not be limited only to embodiments presented in the description of the present application set forth herein.

An assembly of a current sensor and a power conductor according to embodiments of the present application will be described below in more detail with reference to the accompanying drawings.

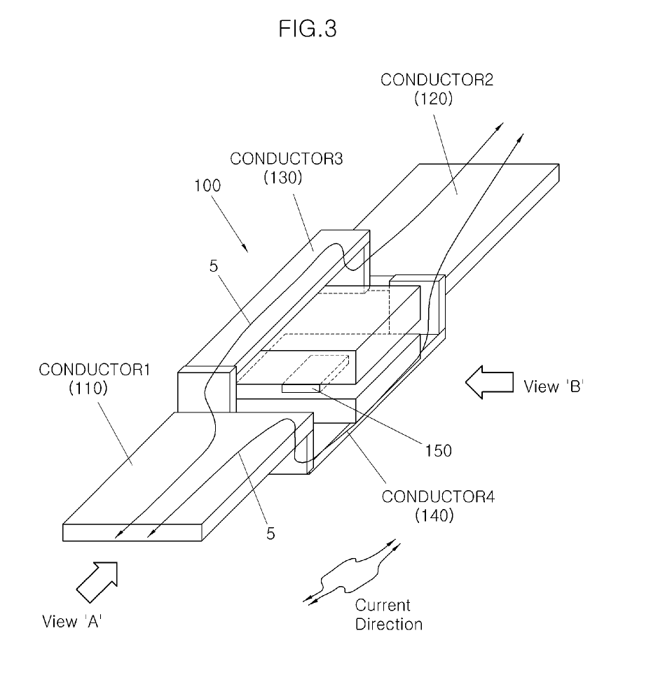

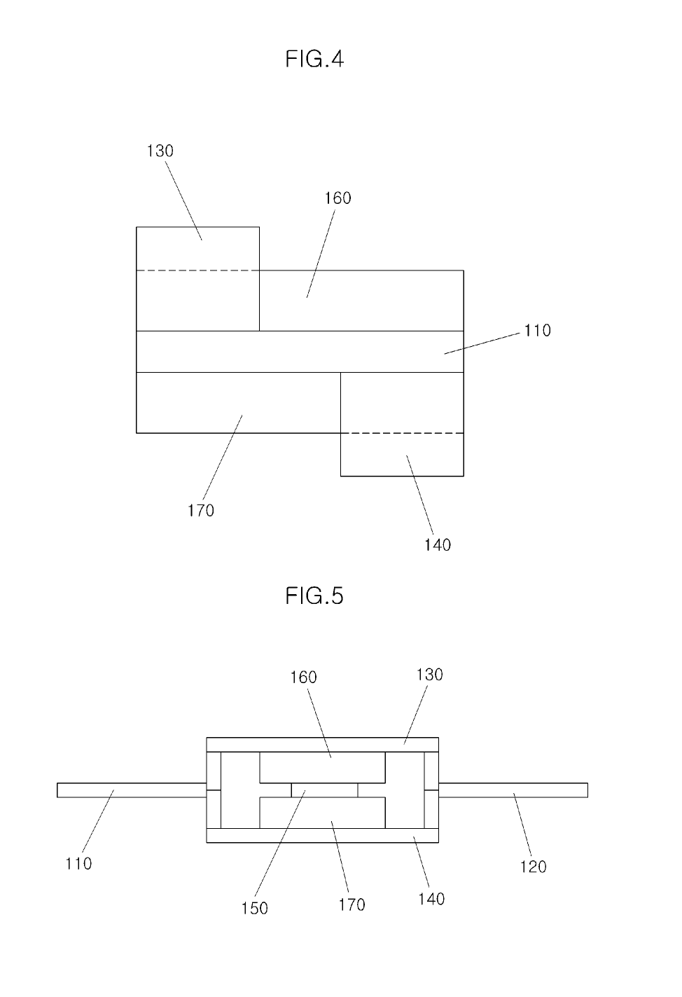

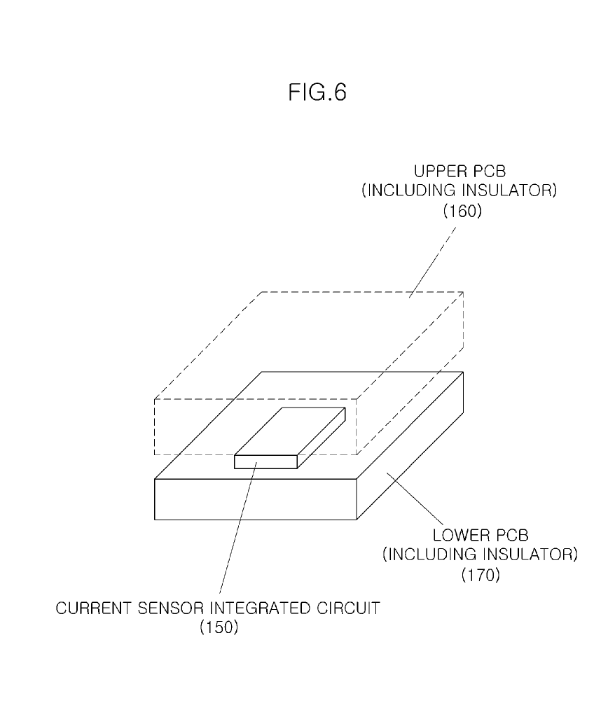

Referring to FIGS. 3 to 6, the assembly of a current sensor and a power conductor, which is designated by reference numeral 100, according to an embodiment of the present application may include power conductors 110, 120, 130, and 140, a current sensor 150, a first circuit module 160, and a second circuit module 170. In this case, the power conductors 110, 120, 130, and 140 may include a first conductor 110, a second conductor 120, a third conductor 130, and a fourth conductor 140.

Accordingly, the assembly of a current sensor and a power conductor 100 according to an embodiment of the present application may include the first conductor 110, the second conductor 120, the third conductor 130, the fourth conductor 140, the current sensor 150, the first circuit module 160, and the second circuit module 170. Here, the first to fourth conductors 110, 120, 130, and 140 are also referred to as “busbars”.

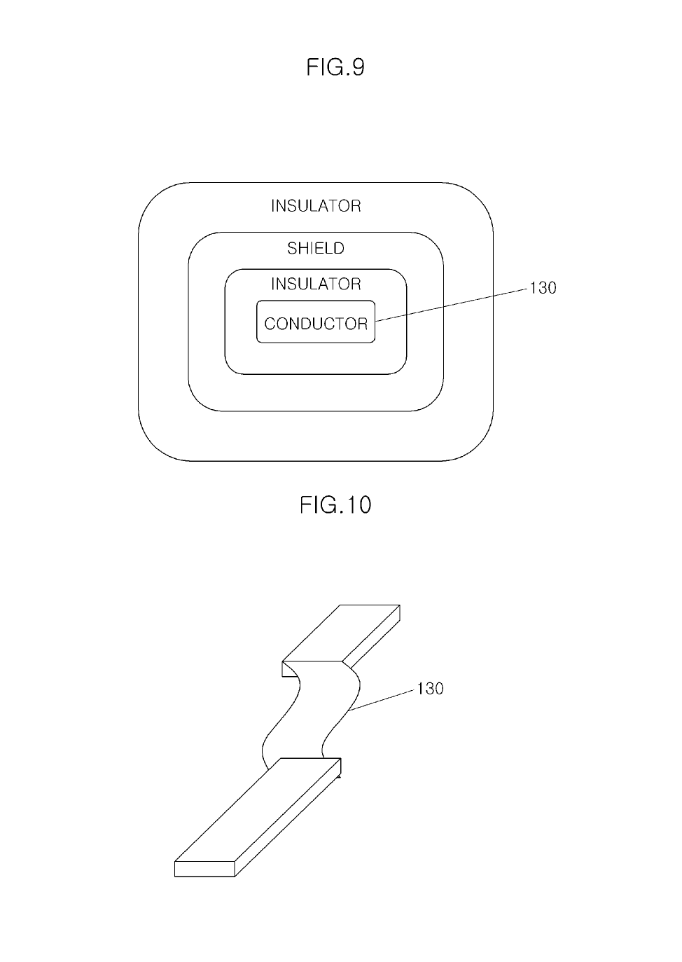

The first conductor 110 allows a current to flow through the third and fourth conductors 130 and 140. In more detail, when a current is supplied from a power supply to the first conductor 110, the first conductor 110 may divide the current and supply the divided currents to the third and fourth conductors 130 and 140. However, since a current is supplied from the power supply to the second conductor 120, the first conductor 110 may add currents flowing from the third and fourth conductors 130 and 140 to be supplied with the added current. Here, a high voltage may be applied to the first conductor 110. In addition, referring to FIG. 9, the first conductor 110 may include an insulator or a shield substance. The insulator and/or shield substance may be formed in an injection molding manner.

The second conductor 120 allows a current to flow through the third and fourth conductors 130 and 140. In more detail, when a current is supplied from the power supply to the second conductor 120, the second conductor 120 may divide the current 5 and supply the divided currents to the third and fourth conductors 130 and 140. However, since a current is supplied from the power supply to the first conductor 110, the second conductor 120 may add currents flowing from the third and fourth conductors 130 and 140 to be supplied with the added current. Here, a high voltage may be applied to the second conductor 120. In addition, referring to FIG. 9, the second conductor 120 may include an insulator or a shield substance. The insulator and/or shield substance may be formed in an injection molding manner.

The third conductor 130 connects the first conductor 110 to the second conductor 120. In more detail, the third conductor 130 may be vertically spaced apart from the fourth conductor 140 by a certain distance, and may connect the first conductor 110 to the second conductor 120. That is, the third and fourth conductors 130 and 140 may be vertically spaced apart from each other by the certain distance and may symmetrically or asymmetrically be formed.

When the third and fourth conductors 130 and 140 are symmetrically formed, the third and fourth conductors 130 and 140 may be formed at symmetrical positions and have symmetrical areas. Therefore, the current flowing through each of the third and fourth conductors 130 and 140 may be a half of the current flowing through the first conductor 110. Here, the certain distance may be a distance within which the current sensor 150 or the like is installed.

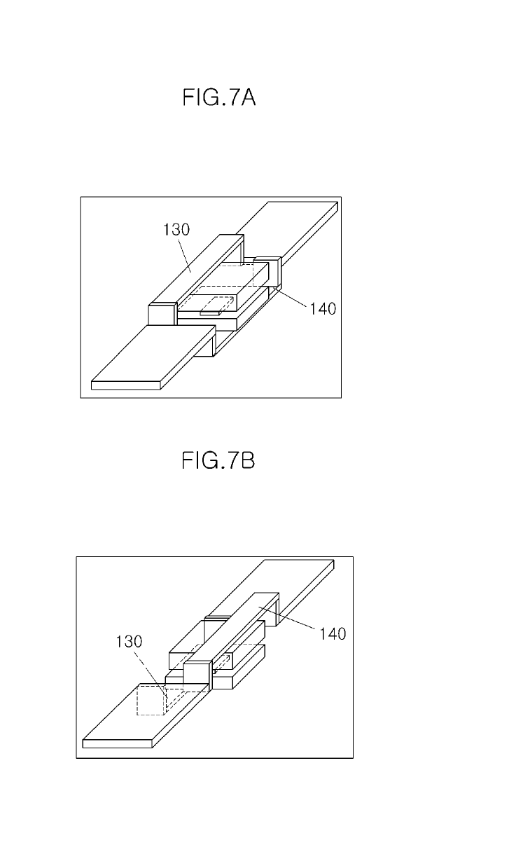

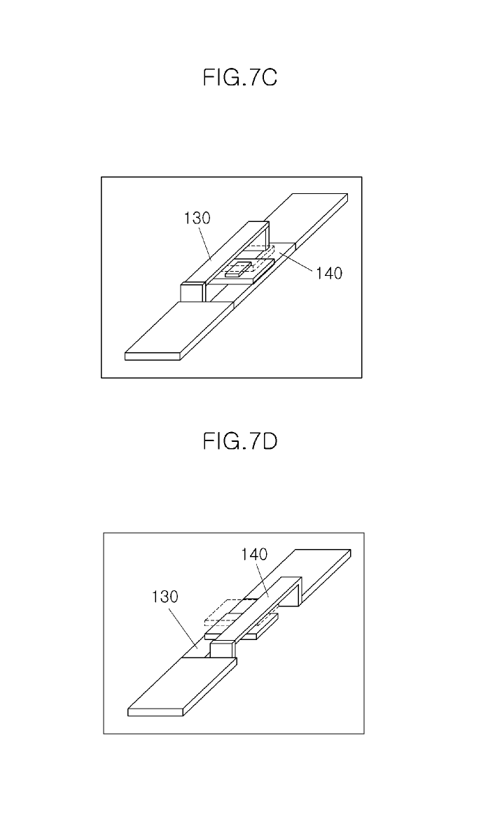

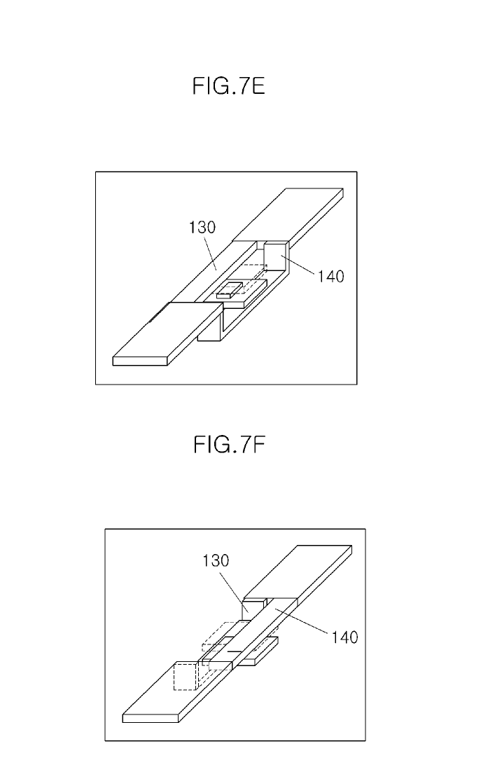

Referring to FIGS. 7A-7F, the third conductor 130 may be vertically spaced apart from the fourth conductor 140 by a certain distance and have various shapes. That is, when the third conductor 130 is formed to be vertically spaced apart from the fourth conductor 140 by only the certain distance, the third conductor 130 may be convexly or concavely formed upward and may also be horizontally installed on the same plane as the first and second conductors 110 and 120. Even though the third conductor 130 has various shapes, the same effect may be exhibited as long as the distance between the third conductor 130, the current sensor 150, and the fourth conductor 140 satisfies a certain level.

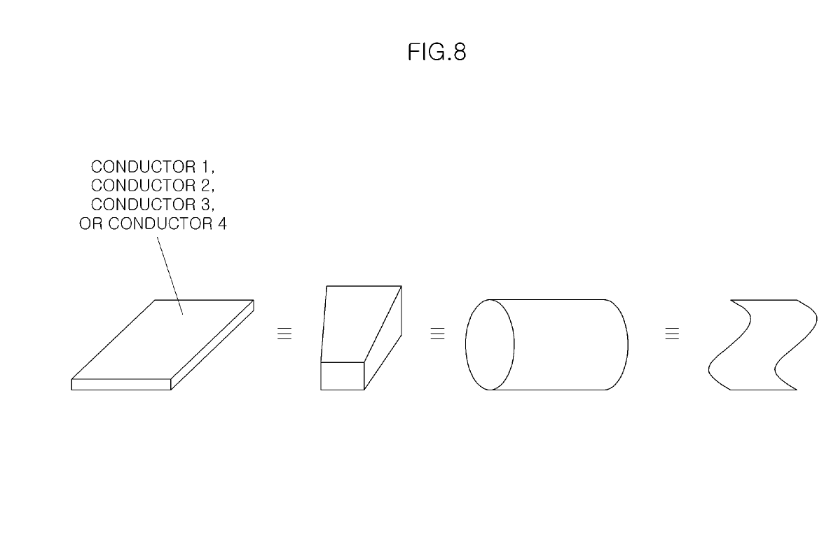

Referring to FIG. 8, the third conductor 130 may have any polyhedral, cylindrical, or streamlined shape as well as having a regular hexahedron shape or a shape bent at a right angle.

Referring to FIG. 9, the third conductor 130 may include an insulator or a shield substance. That is, the conductor may have a structure in which the insulator and the shield substance surround the conductor for insulation and shielding of the conductor. Here, the insulator may be injection molded so as to perform heat dissipation and insulation functions.

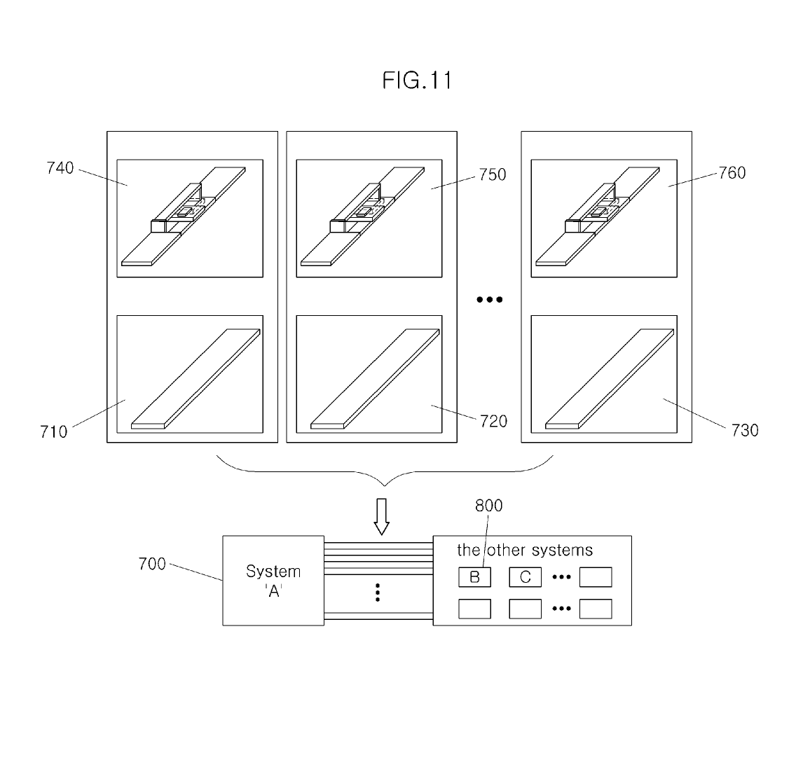

Referring to FIG. 10, the third conductor 130 may connect the first conductor 110 to the second conductor 120 by any angle. Particularly, the power conductor may have a streamlined shape by connection of the conductors 110, 120, and 130.

The fourth conductor 140 is vertically spaced apart from the third conductor 130 by a certain distance and connects the first conductor 110 to the second conductor 120. In more detail, the fourth and third conductors 140 and 130 may be vertically spaced apart from each other by the certain distance and may symmetrically or asymmetrically be formed. When the fourth and third conductors 140 and 130 are symmetrically formed, the fourth and third conductors 140 and 130 may be formed at symmetrical positions and have symmetrical areas. Therefore, the current flowing through each of the fourth and third conductors 140 and 130 may be a half of the current flowing through the first conductor 110. Here, the certain distance may be a distance within which the current sensor 150 or the like is installed. The fourth conductor 140 may include an insulator or a shield substance.

Referring to FIGS. 7A-7F, the fourth conductor 140 may be vertically spaced apart from the third conductor 130 by a certain distance and have various shapes. That is, when the fourth conductor 140 is formed to be vertically spaced apart from the third conductor 130 by only the certain distance, the fourth conductor 140 may be convexly or concavely formed upward and may also be horizontally installed on the same plane as the first and second conductors 110 and 120. Even though the fourth conductor 140 has various shapes, the same effect may be exhibited as long as the distance between the third conductor 130, the current sensor 150, and the fourth conductor 140 satisfies a certain level.

Referring to FIG. 8, the fourth conductor 140 may have any polyhedral, cylindrical, or streamlined shape as well as having a regular hexahedron shape or a shape bent at a right angle.

Referring to FIG. 9, the fourth conductor 140 may include an insulator or a shield substance. That is, the conductor may have a structure in which the insulator and the shield substance surround the conductor for insulation and shielding of the conductor. Here, the insulator may be injection molded so as to perform heat dissipation and insulation functions.

Referring to FIG. 10, the fourth conductor 140 may connect the first conductor 110 to the second conductor 120 by any angle. Particularly, the power conductor may have a streamlined shape by connection of the conductors 110, 120, and 140.

The current sensor 150 is installed between the third and fourth conductors 130 and 140, and senses a magnetic field formed by the third conductor 130 and a magnetic field formed by the fourth conductor 140 to measure currents flowing therethrough. In more detail, the current sensor 150 may be installed between the third and fourth conductors 130 and 140 which are vertically spaced apart from each other by the certain distance and sense the magnetic field formed by the third conductor 130 and the magnetic field formed by the fourth conductor 140 to measure the currents flowing therethrough. Here, the current sensor 150 may be a current sensor integrated circuit.

The first circuit module 160 is installed between the current sensor 150 and the third conductor 130 and is connected to the current sensor 150. That is, the first circuit module 160 may be installed between the third conductor 130 and the current sensor 150 installed between the third and fourth conductors 130 and 140 which are vertically spaced apart from each other by the certain distance, so as to be electrically connected to the current sensor 150.

In addition, the first circuit module 160 may include an insulator for insulation against the third conductor 130. That is, the first circuit module 160 may include the insulator so that an insulation structure is formed in which the first circuit module 160 is insulated from the third conductor 130, the current sensor 150, and the like. In addition, in order to insulate the current sensor 150 and the like from the third conductor 130, an insulator may be added between the third conductor 130 and the first circuit module 160 or the first circuit module 160 may also be replaced with the insulator or an air gap.

Here, the first circuit module 160 may be a current sensor PCB (Printed Circuit Board). Alternatively, the first circuit module 160 may be removed from the assembly since the first circuit module 160 is not an essential component of the present application.

The second circuit module 170 is installed between the current sensor 150 and the fourth conductor 140 and is connected to the current sensor 150. That is, the second circuit module 170 may be installed between the fourth conductor 140 and the current sensor 150 installed between the third and fourth conductors 130 and 140 which are vertically spaced apart from each other by the certain distance, so as to be electrically connected to the current sensor 150.

In addition, the second circuit module 170 may include an insulator for insulation against the fourth conductor 140. That is, the second circuit module 170 may include the insulator so that an insulation structure is formed in which the second circuit module 170 is insulated from the fourth conductor 140, the current sensor 150, and the like. In addition, in order to insulate the current sensor 150 and the like from the fourth conductor 140, an insulator may be added between the fourth conductor 140 and the second circuit module 170 or the second circuit module 170 may also be replaced with the insulator or an air gap. Here, the second circuit module 170 may be a current sensor PCB. Alternatively, the second circuit module 170 may be removed from the assembly since the second circuit module 170 is not an essential component of the present application.

Hereinafter, effects of the assembly of a current sensor and a power conductor according to an embodiment of the present application will be described with reference to the drawings.

Referring to FIG. 11, the assembly of a current sensor and a power conductor according to an embodiment of the present application may connect the system to a power system for an eco-friendly vehicle. For example, when six connection paths are assumed to be present between an inverter system (system A) 700 and a motor system 800, three connection paths 710, 720, and 730 of them may correspond to a power conductor assembly without a current sensor and the other three connection paths 740, 750 and 760 may correspond to an assembly of a current and a power conductor with a current sensor. Here, when the inverter system 700 is assumed to be a system A, the motor system 800 may be a system B and a system C may also be a converter.

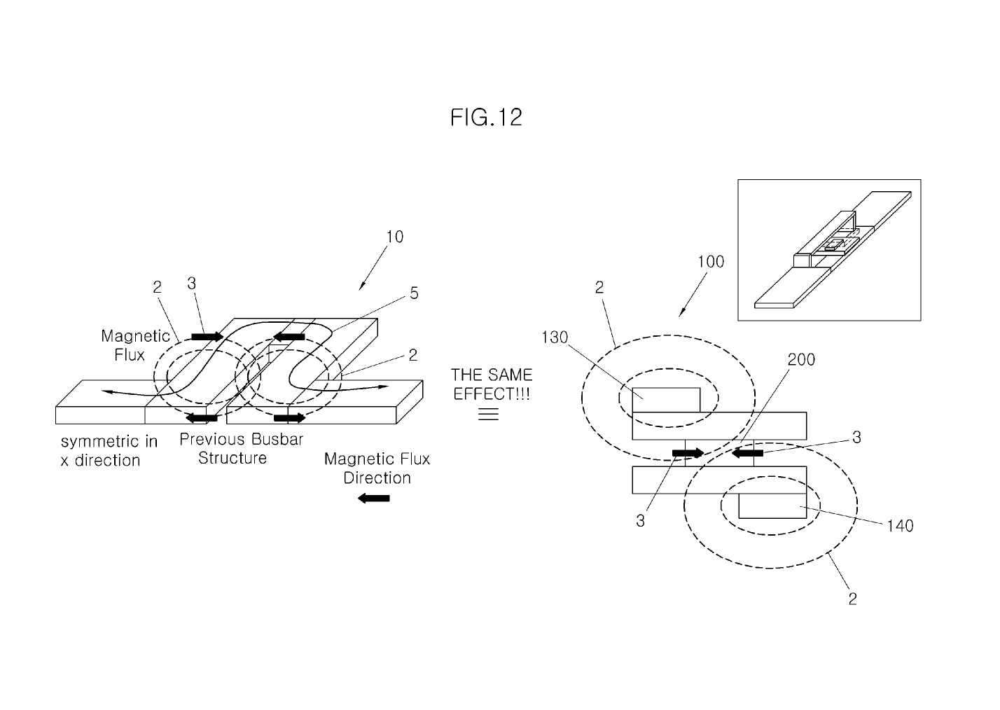

In FIG. 12, a left figure illustrates a conventional conductor 10 and a right figure illustrates the assembly of a current sensor and a power conductor 100 according to an embodiment of the present application. Comparing the left figure with the right figure, it may be shown that directions 3 of magnetic fields generated by currents 5 flowing through the conductor are equal to each other. In more detail, according to the related art, directions 5 of the currents flowing through the conductor 10 are longitudinally opposite to each other and are defined on the basis of the same z-axis height with respect to a current sensor. Thus, the magnetic fields in the opposite directions are formed on the basis of the same z-axis height with respect to the current sensor.

On the other hand, according to the assembly of a current sensor and a power conductor 100 according to an embodiment of the present application, current directions 5 are longitudinally equal to each other, whereas current paths are not defined on the basis of the same z-axis height. Accordingly, a current path of the third conductor 130 is arranged above the current sensor 150 and a current path of the fourth conductor 140 is arranged beneath the current sensor 150. Since the magnetic field in the vicinity of each current forms a magnetic flux loop 2 on the basis of the associated current path, a magnetic field direction 3 is defined to the right beneath the third conductor 130 and a magnetic field direction 3 is defined to the left above the fourth conductor 140. Accordingly, by the magnetic field directions 3 defined by the assembly of a current sensor and a power conductor 100 according to an embodiment of the present application, the magnetic fields having the same directions as the magnetic field directions 3 in the conventional conductor 10 may be equally realized at the height of the current sensor 150.

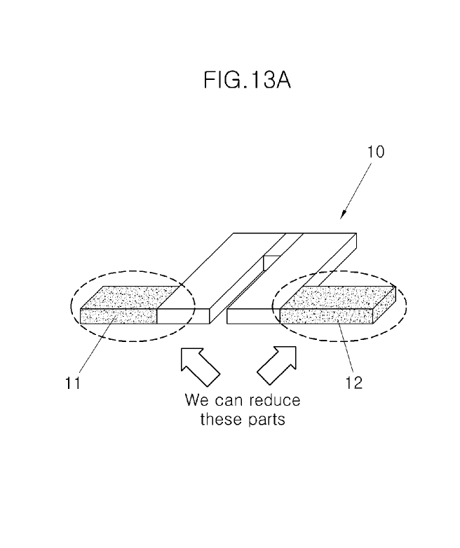

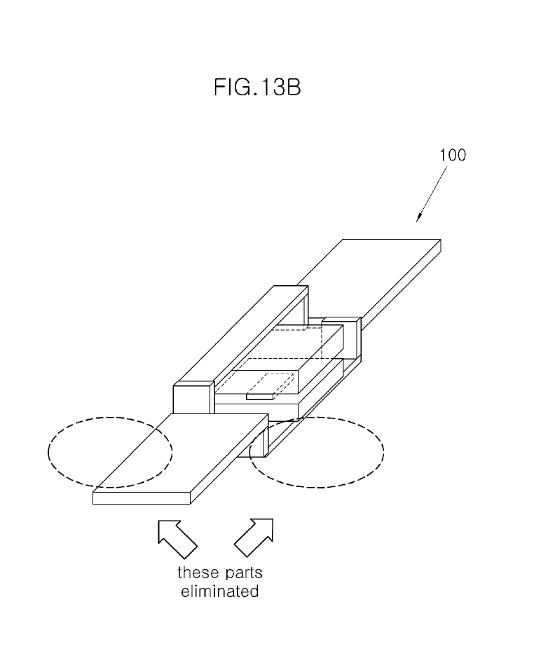

FIG. 13A illustrates a conventional conductor 10 and FIG. 13B illustrates the assembly of a current sensor and a power conductor 100 according to an embodiment of the present application. Comparing FIG. 13A with FIG. 13B, since first and second conductors 11 and 12 are formed at both sides of a turn portion in the conventional conductor 10, the conductor has an increased size. On the other hand, since no turn portion is present and no conductors are formed at both sides of the turn portion in the assembly of a current sensor and a power conductor 100 according to an embodiment of the present application, the conductor has a small size.

In addition, when the third and fourth conductors 130 and 140 are symmetrically designed in the assembly of a current sensor and a power conductor 100 according to an embodiment of the present application, the divided current is reduced half and thus the busbar may have a width decreased in proportion to the reduced current. Therefore, the conductor may have a further reduced size compared to the conventional conductor 10.

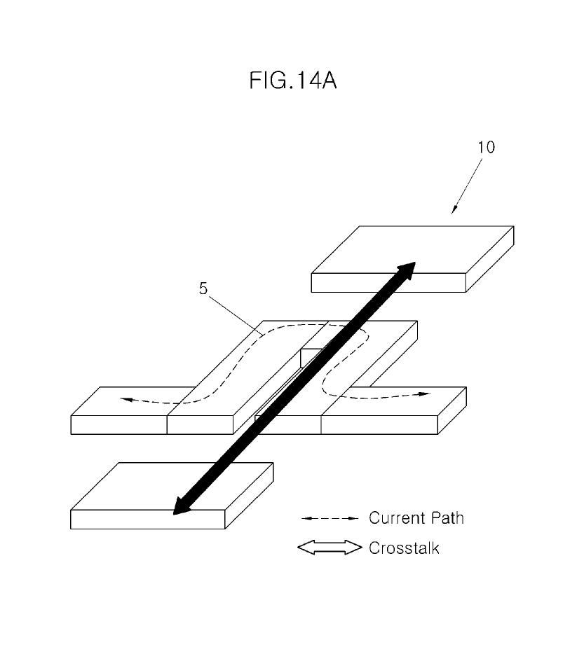

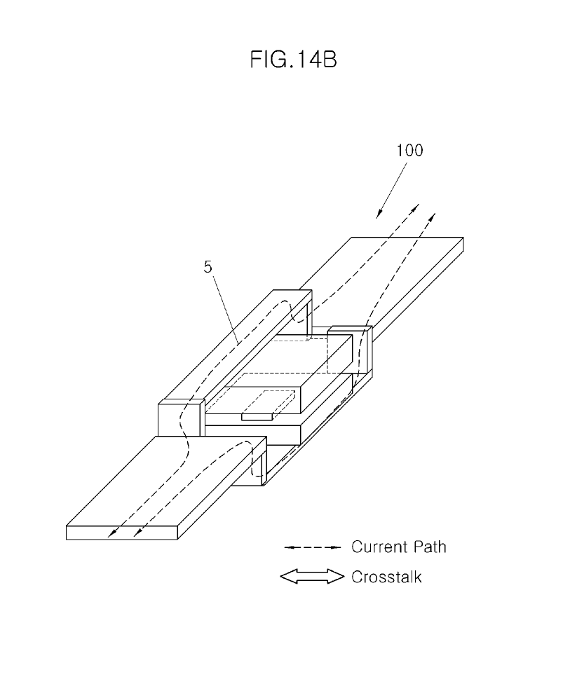

FIG. 14A illustrates a conventional conductor 10 and FIG. 14B illustrates the assembly of a current sensor and a power conductor 100 according to an embodiment of the present application. Comparing FIG. 14A with FIG. 14B, since a transversal current path 5 is mainly defined in the conventional conductor 10, a longitudinal magnetic field is formed, thereby causing crosstalk and noise in peripheral low-voltage electric devices. However, since the longitudinal current path 5 is mainly defined in the assembly of a current sensor and a power conductor 100 according to an embodiment of the present application, the longitudinal magnetic field is formed, thereby preventing crosstalk from occurring in peripheral low-voltage electric devices.

In accordance with an optimally sized assembly of a current sensor and a power conductor according to embodiments of the present application, since crosstalk due to magnetic field interference between conductors is reduced, a current sensor can have improved performance and the product can have improved EMC and electric performance.

In accordance with the optimally sized assembly of a current sensor and a power conductor according to embodiments of the present application, since the conductors have a simple structure by the reduced sizes of an inflection portion and a busbar, compared to existing conductors having a complicated structure, the conductors can be miniaturized and lightened and the assembly of a current sensor and a power conductor can be manufactured in an improved manner.

In accordance with the optimally sized assembly of a current sensor and a power conductor according to embodiments of the present application, since a separate shield assembly is not required, the assembly of a current sensor and a power conductor can be simply designed.

While the present application has been described with respect to specific embodiments, it will be apparent to those skilled in the art that various changes and modifications may be made without departing from the spirit and scope of the application as defined in the following claims.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An assembly of a current sensor and a power conductor, the assembly comprising:
a first conductor;
a second conductor spaced apart from the first conductor;
a third conductor connecting one end of the first conductor to one end of the second conductor; and
a fourth conductor vertically spaced apart from the third conductor and connecting one end of the first conductor to one end of the second conductor, a fixed space being defined between the third and fourth conductors.

2. The assembly of claim 1, further comprising a current sensor installed in the fixed space to sense a magnetic field formed by the third conductor and a magnetic field formed by the fourth conductor so as to measure currents flowing therethrough.

3. The assembly of claim 2, further comprising a first circuit module installed between the current sensor and the third conductor to be connected to the current sensor.

4. The assembly of claim 3, wherein the first circuit module comprises an insulator.

5. The assembly of claim 2, further comprising an insulator arranged between the current sensor and the third conductor.

6. The assembly of claim 2, further comprising a second circuit module installed between the current sensor and the fourth conductor to be connected to the current sensor.

7. The assembly of claim 6, wherein the second circuit module comprises an insulator.

8. The assembly of claim 2, further comprising an insulator arranged between the current sensor and the fourth conductor.

9. The assembly of claim 1, wherein at least one of the first, the second, the third, and the fourth conductors comprises an insulator or a shield substance.

10. The assembly of claim 1, wherein the third and the fourth conductors are arranged alternately with each other.

11. The assembly of claim 1, wherein the third or the fourth conductor has any one of a regular hexahedron shape, a shape bent at a right angle, a polyhedral shape, a cylindrical shape, and a streamlined shape.

12. The assembly of claim 1, wherein a position and an area of the third and of the fourth conductors are symmetrical or are asymmetrical to each other.

13. The assembly of claim 1, wherein a current flowing in each path of the third and of the fourth conductors is a half of a current supplied to the assembly.

14. The assembly of claim 9, wherein the insulator or the shield substance is formed in an injection molding process.
